(19) United States
(12) Patent Application Publication
(10) Pub. No.: US 2006/0240677 A1
(43) Pub. Date: Oct. 26, 2006

(54) Method for manufacturing semiconductor device and substrate processing apparatus

(75) Inventors: Sadayoshi Horii, Tokyo (JP); Hironobu Miya, Tokyo (JP); Yoshiaki Hashiba, Tokyo (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignees: HITACHI KOKUSAI ELECTRIC INC.,, TOKYO (JP); SUSUMU HORITA, NOMI-SHI (JP)

(21) Appl. No.: 10/528,450

(22) PCT Filed: Sep. 19, 2003
(86) PCT No.: PCT/JP03/11988

§ 371 Date: May 22, 2006

(30) Foreign Application Priority Data
Sep. 20, 2002 (JP) 2002-276076

(51) Int. Cl. H01L 21/31; H01L 21/469

(52) U.S. Cl. 438/770; 438/782

(57) ABSTRACT

An oxidizer supply device (30) comprises an ozonizer (31) for generating ozone (32), a bubbler (34) wherein deionized water (35) is kept and an ozone supply pipe (33) for supplying ozone (32) from the ozonizer (31) is immersed in the deionized water (35) so as to bubble ozone, and a supply pipe (36) for supplying oxidizer (37) containing OH* generated by bubbling of the ozone (32). The device (30) is connected to a feed pipe (18) of an oxide film forming device (10). The oxidizer containing OH* generated by bubbling ozone in the water possesses a powerful oxidizing effect so oxide film can be formed on the wafer at a relatively low temperature in a short time. Semiconductor devices or circuit patterns previously formed on the wafer can be prevented from being damaged by plasma since no plasma is used. The throughput, performance and reliability of the oxide film forming device are therefore improved.

### TECHNICAL FIELD

The present invention relates to a manufacturing method for semiconductor devices, and relates to technology effectively utilized in, for example, manufacturing methods for semiconductor integrated circuit devices (hereafter called IC) including a process for forming an oxide film on the semiconductor wafer (hereafter called wafer) that forms the IC, and an etching process, and a substrate surface cleaning process, and a thin film forming process using CVD, and a cleaning process inside the processing chamber.

### BACKGROUND ART

In the oxide film forming process that utilizes heat oxidation in the IC manufacturing process of the prior art, the oxide film is formed on the wafer by heat treatment at high temperatures using oxygen (for example, see Japanese Patent Non-Examined Publication No. 7-176498). However, as continual advances were made in making ICs more highly integrated and semiconductor devices and circuit patterns became tinier, changes occurring in the materials and properties of semiconductor devices formed beforehand on the wafer by heat processing at high temperatures are an issue of serious concern. Resolving this problem required lowering the heat processing temperature. Ozone (O₃) was considered an oxidizer capable of lowering the heat processing temperature during forming of the oxide film. The heat processing temperature when forming the oxide film using oxygen is for example a high temperature of 700° C. to 1000° C., however the heat processing temperature when forming the oxide film using ozone has been attempted at temperatures of 500° C. or less.

In the manufacturing method for ICs of the prior art, methods for forming an oxide film at temperatures of 500° C. or less, utilized plasma to activate oxygen or reactive substance in order to oxidize the wafer.

In the oxide film forming method using ozone, an adequate oxidizing speed could not be achieved at low temperatures. It is necessary to set the heat processing temperature to 400° C. or more. However, the ozone decomposes at heat processing temperatures of 400° C. or more, creating the problem that there ozone oxidizing effect is not obtained. In other words, the oxidizing power of the ozone is not strong enough to compensate for heat processing at lower temperatures. This situation increased the demand for a new type of oxidizer.

Methods for forming an oxide film using plasma to activate oxygen or reactive substance in order to oxidize the wafer contained the problem that they damaged the semiconductor device or circuit pattern formed beforehand on the wafer due to plasma impacts.

The present invention has the object of providing a manufacturing method for semiconductor devices and an oxide film forming technology capable of forming an oxide film at a low temperature.

### DISCLOSURE OF INVENTION

Characteristics features of the present invention disclosed in these specifications are as follows.

1. A manufacturing method for semiconductor devices comprising the steps of: loading an object to be processed into a processing chamber, generating an activated gas by bubbling ozone in fluid containing at least hydrogen atoms, supplying the generated gas into the processing chamber and processing the object to be processed, and unloading the object to be processed from the processing chamber after processing, wherein the processing temperature in the step for processing the object to be processed is greater than the temperature of the fluid containing hydrogen atoms.

2. A manufacturing method for semiconductor devices comprising the steps of: loading an object to be processed into a processing chamber, generating an activated gas by bubbling ozone in fluid containing at least hydrogen atoms, supplying the generated gas into the processing chamber and processing the object to be processed, and unloading the object to be processed from the processing chamber after processing, wherein the processing temperature in the step for processing the object to be processed is 100 to 500° C.

3. A manufacturing method for semiconductor devices comprising the steps of: loading an object to be processed into a processing chamber, generating an activated gas by bubbling ozone in fluid containing at least hydrogen atoms, supplying the generated gas into the processing chamber and forming an oxide film on the object to be processed, and unloading the object to be processed from the processing chamber after processing.

4. A manufacturing method for semiconductor devices comprising the steps of: loading an object to be processed into a processing chamber, generating an activated gas by bubbling ozone in fluid containing at least hydrogen atoms, supplying the generated gas into the processing chamber and etching an oxide film formed on the object to be processed, and unloading the object to be processed from the processing chamber after processing.

5. A manufacturing method for semiconductor devices comprising the steps of: loading an object to be processed into a processing chamber, generating an activated gas by bubbling ozone in fluid containing at least hydrogen atoms, supplying the generated gas and material gas into the processind chamber and forming a film on the object to be processed by the thermal CVD method, and unloading the object to be processed from the processing chamber ahter processing.

6. A manufacturing method for semiconductor devices comprising the steps of: loading an object to be processed into a processing chamber, processing the object to be processed in the processing chamber, unloading the object to be processed from the processing chamber after processing, generating an activated gas by bubbling ozone in fluid containing at least hydrogen atoms, supplying the generated gas into the processing chamber with the object to be processed unloaded to remove contamination substance in the processing chamber.

7. A manufacturing method for semiconductor devices according to claim 1, wherein in the step for processing the object to be processed, an oxide film is formed on the object to be processed or a film is formed on the object to be processed by thermal CVD method in an atmosphere containing the generated gas and material gas.

8. A manufacturing method for semiconductor devices according to claim 1, wherein in the step for processing the object to be processed, an oxide film formed on the surface of the object to be processed is etched, or a semiconductor or a metal as the object to be processed is etched, or a natural oxide film or organic contamination substance or metal contamination substance formed on the surface of the object to be processed is removed.

9. A manufacturing method for semiconductor devices according to claim 7, wherein the processing temperature in the step for processing the object to be processed is 100 to 500° C.

10. A manufacturing method for semiconductor devices according to claim 8, wherein the processing temperature in the step for processing the object to be processed is 50 to 400° C.

11. A manufacturing method for semiconductor devices according to claim 2, wherein in the step for processing the object to be processed, an oxide film is formed on the surface of the object to be processed, or a film is formed on the object to be processed by thermal CVD method in an atmosphere containing the generated gas and material gas.

12. A manufacturing method for semiconductor devices according to claim 1, wherein the hydroxyl (OH) radicals are generated in the step for generating the activated gas.

13. A manufacturing method for semiconductor devices according to claim 1, wherein the activated gas is a gas containing a hydroxyl.

14. A manufacturing method for semiconductor devices according to claim 1, wherein the fluid for bubbling the ozone is a fluid containing at least hydrogen (H) atoms and oxygen (O) atoms.

15. A manufacturing method for semiconductor devices according to claim 1, wherein the fluid for bubbling the ozone is water (H₂O).

16. A manufacturing method for semiconductor devices according to claim 1, wherein the fluid for bubbling the ozone is deionized water (pure water).

17. A manufacturing method for semiconductor devices according to claim 1, wherein the fluid for bubbling the ozone is hydrogen peroxide water solution (H₂O₂).

18. A manufacturing method for semiconductor devices according to claim 1, wherein the fluid for bubbling the ozone contains hydrogen chloride (HCl).

19. A manufacturing method for semiconductor devices according to claim 1, wherein the fluid for bubbling the ozone is a fluid containing at least a hydroxyl.

20. A substrate processing apparatus comprising: a processing chamber for processing an object to be processed, a heater for heating the object to be processed in the processing chamber, an ozonizer for generating ozone, a bubbler for generating activated gas by bubbling ozone generated by the ozonizer in fluid containing at least hydrogen atoms, a supply pipe for supplying the activated gas generated by the bubbler into the processing chamber, and a control means for regulating the processing temperature during processing of the object to be processed so that the processing temperature is higher than the temperature of the fluid containing the hydrogen atoms.

21. A substrate processing apparatus comprising: a processing chamber for processing an object to be processed, a heater for heating the object to be processed in the processing chamber, an ozonizer for generating ozone, a bubbler for generating activated gas by bubbling ozone generated by the ozonizer in fluid containing at least hydrogen atoms, and a supply pipe for supplying the activated gas generated by the bubbler into the processing chamber, and a control means for regulating the processing temperature during processing of the object to be processed so that the processing temperature is 100 to 500° C.

22. A substrate processing apparatus comprising: a processing chamber for processing an object to be processed, a heater for heating the object to be processed in the processing chamber, an ozonizer for generating ozone, a bubbler for generating activated gas by bubbling ozone generated by the ozonizer in fluid containing at least hydrogen atoms, and a supply pipe for supplying the activated gas generated by the bubbler into the processing chamber, wherein an oxide film is formed on the object to be processed in the processing chamber.

23. A substrate processing apparatus comprising: a processing chamber for processing an object to be processed, a heater for heating the object to be processed in the processing chamber, an ozonizer for generating ozone, a bubbler for generating activated gas by bubbling ozone generated by the ozonizer in fluid containing at least hydrogen atoms, and a supply pipe for supplying the activated gas generated by the bubbler into the processing chamber, wherein etching is performed on an oxide film formed on the object to be processed in the processing chamber.

24. A substrate processing apparatus comprising: a processing chamber for processing an object to be processed, a heater for heating the object to be processed in the processing chamber, an ozonizer for generating ozone, a bubbler for generating activated gas by bubbling ozone generated by the ozonizer in fluid containing at least hydrogen atoms, a supply pipe for supplying the activated gas generated by the bubbler into the processing chamber, and a supply pipe for supplying gas containing at least one of either a semiconductor element or a metallic element, wherein a metallic oxide film or a semiconductor oxide film is formed on the object to be processed by thermal CVD method in an atmosphere containing the generated gas and at least one of either a semiconductor element or a metallic element in the processing chamber.

Forming an oxide film at a low temperature as described previously, requires an oxidizer with ample oxidizing power even at low temperatures. Taking notice of the fact that OH⁻ (hydroxyl ions) or OH* (hydroxyl radicals) are an oxidant having the most powerful oxidizing force in the natural environment, the inventors discovered the possibility of efficiently generating OH* for use as an oxidizer to form oxide film at low temperatures of 500° C. or less.

Usually the ozone is bubbled in the water in order to melt the ozone. However, the inventors discovered the facts that bubbling the ozone in water generates OH* and that radicalized OH* is discharged into the air by bubbling. The reaction between ozone and water when bubbling ozone in the water is expressed by the following formula (1).
H₂O+O₃→2OH*+½×O₂ (1)

Other methods considered for generating OH* include a method for mixing steam with the ozone. However, this method is incapable of efficiently generating OH* since the probability in which the water molecules in the gaseous state collide and react with the ozone is low. The inventors therefore used a method of bubbling ozone in water and were able to generate OH* with still greater efficiency and form an oxide film at a low temperature.

### BRIEF DESCRIPTION OF DRAWINGS

FIG. 1 is a concept diagram showing the experimental device for illustrating the principle of the present invention;

FIG. 2 is a graph showing those experiment results;

FIG. 3 is a side cross sectional view showing the oxide film forming device of the first embodiment of the present invention;

FIG. 4 is a plan cross sectional view showing a section of the multichamber device of the second embodiment of the present invention;

FIG. 5 is a side cross sectional view showing the cleaning unit;

FIG. 6 is a side cross sectional view showing the MOCVD device of the third embodiment of the present invention.

### BEST MODE FOR CARRYING-OUT THE INVENTION

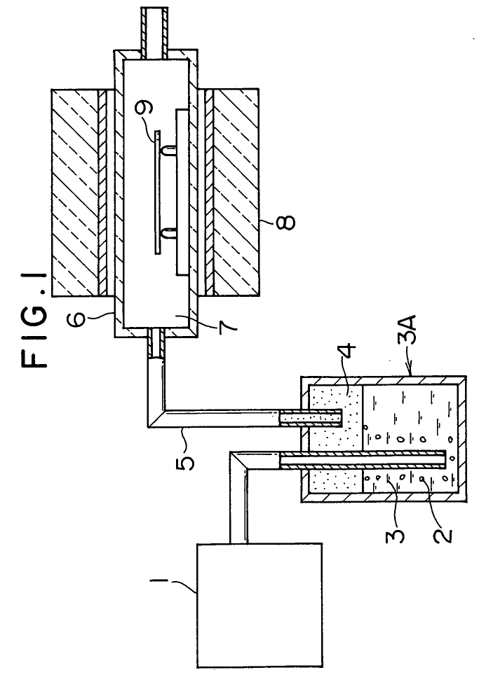

In order to investigate the oxidizing power at low temperature of gas containing OH* generated by bubbling ozone in water, the present inventors performed experiments by using a gas generated by bubbling ozone in deionized water to form an oxide film on a silicon wafer serving as the object to be processed. FIG. 1 shows the oxide film forming device used in the experiment. In FIG. 1, ozone 2 generated by an ozonizer 1 is bubbled in a deionized water 3 inside a bubbler 3A. A feed pipe 5 supplies gas (hereafter called the oxidizer) 4 containing OH* generated by bubbling, into a processing chamber 7 formed by a process tube 6 made of quartz. The processing chamber 7 is heated to 200° C., 300° C., 400° C. and 500° C. by a resistance-heating type heater unit 8. A silicon wafer 9 serving as the object to be processed is supported by a support stand installed in the processing chamber 8.

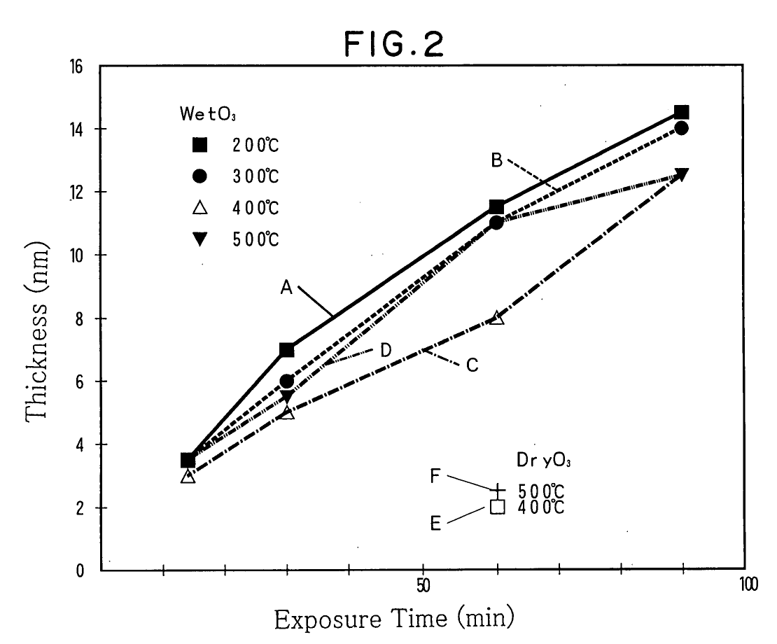

FIG. 2 is a graph showing the interrelation of the oxide film thickness and oxide film forming time obtained in the experiment. The horizontal axis in FIG. 2 is the oxide film forming time (time that the silicon wafer was exposed to the gas generated by bubbling the ozone in the deionized water) in minutes. The vertical axis is the thickness (nm) of the oxide film. The solid line A shows when gas (hereafter called wet ozone) generated by bubbling the ozone in the deionized water was supplied to the processing chamber heated to 200° C. The broken line B shows when the wet ozone was supplied to a processing chamber heated to 300° C. The chain line C shows when the wet ozone was supplied to a processing chamber heated to 400° C. The chain double-dashed line D shows when the wet ozone was supplied to a processing chamber heated to 500° C. The point E shown by a [(square) for purposes of comparison, shows when non-bubbled ozone (hereafter called dry ozone) was supplied to a processing chamber heated to 400° C. The point F shown by a +(+ mark) for purposes of comparison shows when dry ozone was supplied to a processing chamber heated to 500° C.

As clearly shown in FIG. 2, in spite of low temperatures of 200° C., 300° C., 400° C. and 500° C., the oxide film forming method using wet ozone has a film forming speed 4 to 6 times greater than the oxide film forming method using dry ozone. This experiment therefore proved that the semiconductor device manufacturing method characterized by a step for generating activated gas by bubbling ozone in water, and a step for processing the object to be processed using the generated gas, was capable of forming an oxide film on the object to be processed at low temperatures (at least 200° C. to 500° C.) compared to the case when using dry ozone.

During the above experiment, a white deposit was observed near the exhaust opening of the process tube made from quartz (SiO₂) in the experimental device of FIG. 1. These white deposits were found to be powder of silicon oxide (SiO₂). These deposits were assumed to occur from silicon oxide being dispersed into the gaseous phase due to etching of the process tube by wet ozone and then forming as a deposit in the non-heated part of the process tube due to cooling. Based on the above assumption, a semiconductor device manufacturing method characterized by a step for generating activated gas by bubbling ozone in water, and a step for processing the object to be processed using the generated gas was found capable of etching silicon oxide.

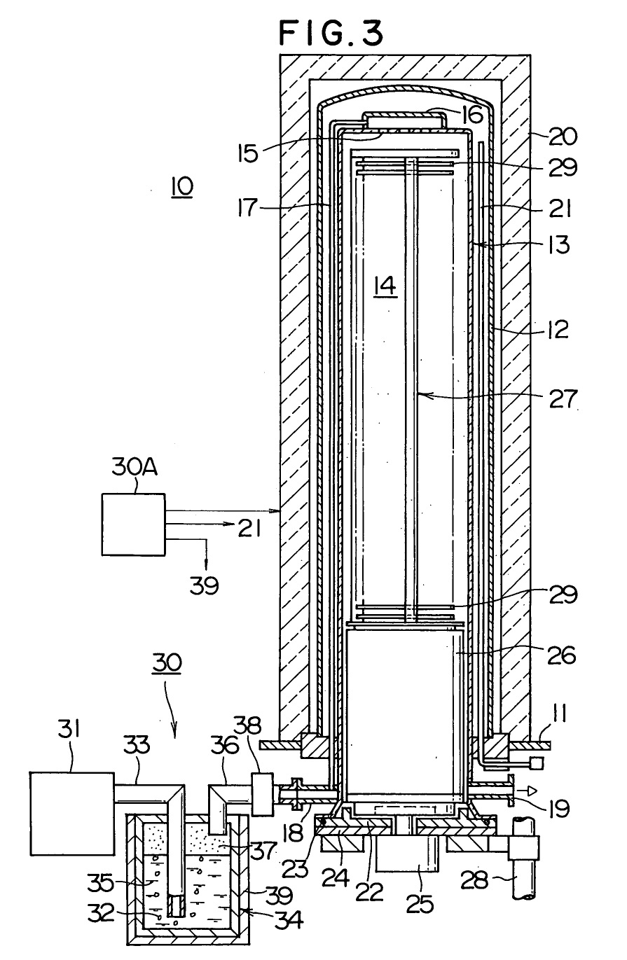

FIG. 3 shows the batch type hot wall oxide film forming device (hereafter called oxide film forming device) for implementing the oxide film forming process in the semiconductor device manufacturing method of the present invention.

An oxide film forming device 10 shown in FIG. 3 is first of all described. The oxide film forming device 10 includes a heat equalizing tube 12 and a reaction tube (process tube) 13 installed mutually concentric and supported perpendicularly in a case 11. Heat-resistant materials such as silicon carbide (SiC) are utilized in the heat equalizing tube 12 installed on the external side. The heat equalizing tube 12 has a cylindrical shape. The top end of the heat equalizing tube 12 is sealed and the bottom end is opened. The reaction tube 13 installed on the inner side is made from a heat-resistant material such as quartz (SiO₂). The reaction tube 13 has a cylindrical shape. The top end of the reaction tube 13 is sealed and the bottom end is opened. The hollow section of the cylindrical structure forms a processing chamber 14. Multiple blow vents 15 are formed on the ceiling wall of the reaction tube 13. A diffusion section 16 on the ceiling wall is formed to cover the blow vents 15. The top edge of a connecting pipe 17 connects to the diffusion section 16. The middle section of the connecting pipe 17 is arranged along the outer circumferential surface of the reaction tube 13. The bottom end of the connecting pipe 17 is connected to a feed pipe 18 arranged radially at the bottom end of the reaction tube 13. The end of an exhaust pipe 19 connects to the bottom end of the reaction tube 13. The other end of the exhaust pipe 19 is connected to an exhaust device (not shown in drawing) made from a pump, etc.

A heater unit 20 is installed concentrically in the external side of the heat equalizing tube 12. A heater unit 20 is vertically supported in the case 11. The heater unit 20 is designed to heat to a specified temperature distribution or a uniform heat throughout the processing chamber 14. A thermocouple 21 for measuring the temperature of the processing chamber 14 is installed perpendicularly in the external side of the reaction tube 13 which is the inner side of the heat equalizing tube 12 (between the heat equalizing tube 12 and reaction tube 13). The measurement results from the thermocouple 21 are used for feedback control of the heater unit 20.

A base 22 formed from for example quartz in a disk shape is installed in the bottom end opening of the reaction tube 13. The base 22 seals the processing chamber 14 airtight by way of a seal ring 23 on the lower end surface of the reaction tube 13. The base 22 is installed on top of a disc-shaped seal cap 24. A rotating shaft 25 functioning as a rotating mechanism is inserted perpendicularly through the seal cap 24. A heat-blocking cap 26 is vertically installed on the base 22. A boat 27 is vertically installed on the heat-blocking cap 26. The rotating shaft 25 is structured to rotate the heat-blocking cap 26 and the boat 27. The boat 27 is structured to hold multiple substrates as the object to be processed or in other words wafers 29 arrayed horizontally in the center. The seal cap 24 is structured to move vertically upwards and downwards via a boat elevator 28.

An oxidizer supply device 30 for supplying oxidizer generated by bubbling ozone in deionized water (pure water), is connected to the feed pipe 18 by way of a mass flow controller (MFC) 38 that functions as the flow control means. The oxidizer supply device 30 is comprised of an ozonizer 31 for generating ozone 32, a bubbler 34 wherein deionized water 35 is kept and the blow vent of an ozone supply pipe 33 for supplying ozone 32 generated by the ozonizer 31 is immersed in the deionized water 35 so as to form ozone bubbles, and a supply pipe 36 for supplying an oxidizer 37 containing OH*(OH radical) generated by bubbling ozone 32 in the deionized water 35 from the bubbler 34 to the feed pipe 18. A heater 39 for heating the deionized water 35 inside the bubbler 34 is installed inside the bubbler 34. The deionized water 35 may also be heated during bubbling by the heater 39. The deionized water 35 may be at room temperature during bubbling, but may also be at a temperature higher than room temperature. For example a temperature that boils may be used. Deionized water (pure water) is particularly preferable as the liquid used for bubbling. Pure water is preferable because it contains very few impurities, prevents the ozone from being consumed by the impurities in the water during bubbling, and efficiently generates OH radicals. Deionized water (pure water) offers the additional advantage that good quality oxide film, or in other words, highly stable film with favorable electrical characteristics can be produced since the pure water has few impurities.

The oxide film forming device 10 contains a temperature controller 30A. The heater unit 20, the thermocouple 21 and the heater 39 are connected to the temperature controller 30A. The temperature controller 30A controls the heater unit 20 and the heater 39 so that the processing temperature during wafer oxidation will be greater than the temperature of the deionized water 35 within the bubbler 34 or so that the temperature will be between 100 and 500° C.

The oxide film forming process in the IC manufacturing method as one embodiment of the present invention by means of the oxide film forming device as mentioned above is described next.

A silicon wafer (hereafter called wafer) 29 to be formed with oxide film is loaded (wafer changing) onto the boat 27 by a wafer transfer device (not shown in drawing). When the specified number of wafers 29 are loaded into the boat 27, the boat 27 is raised by the boat elevator 28 and loaded into the processing chamber 14 of the reaction tube 13 (boat loading). When the boat 27 arrives at the upper limit, the seal cap 24 and the base 22 contact the lower end of the reaction tube 13 by way of the seal ring 23. The reaction tube 13 is now closed in a sealed state so that the processing chamber 14 is sealed. When closed up in a sealed state, the processing chamber 14 is exhausted to a specified pressure by the exhaust pipe 19 and heated to a specified relatively low temperature as the oxide film forming method by heating from 100° C. to 500° C. with the heater unit 20. The controller 30A performs feedback control using the measurement results of the thermocouple 21 to regulate the temperature in the processing chamber 14 with the heater unit 20 to reach a specified temperature. The rotating shaft 25 rotates the heat-blocking cap 26 and the boat 27. The oxidizer 37 containing OH* generated by bubbling ozone in deionized water, is supplied from the oxidizer supply device 30 via the mass flow controller 38 and by way of the feed pipe 18 and connecting pipe 17, to the processing chamber 14. In other words, the ozonizer 31 blows the ozone 32, from the blow vent of the ozone supply pipe 33 into the deionized water 35 to bubble it. When the ozone 32 is bubbled in the deionized water 35, the oxidizer 37 containing OH* is generated as described in formula (1), and discharged into the upper space of the deionized water 35 within the bubbler 34. If using deionized water 35 in this case, the reaction of formula (1) efficiently occurs. The temperature controller 30A at this time regulates the heater unit 20 and the heater 39 so that the processing temperature becomes higher than the temperature of the bubbling deionized water 35. The supply pipe 36 extracts the oxidizer 37 discharged into the space above the deionized water 35 within the bubbler 34. The mass flow controller 38 then supplies the oxidizer 37 to the feed pipe 18. The oxidizer 37 supplied to the feed pipe 18 flows along the connecting pipe 17 and reaches the internal chamber of the diffusion section 16, is diffused within the internal chamber of the diffusion section 16 and blown out from the blow vent 15 in a shower to the processing chamber 14. The oxidizer 37 is supplied by the mass flow controller 38 at a specified flow rate.

The oxide film is formed on the water 29 by the oxidizer 37 contacting the wafer 29 while flowing downstream in the processing chamber 14 due to the exhaust force of the exhaust pipe 19. The oxidizer 37 at this time comes in uniform contact with the wafer 29 surface due to the rotation of the boat 27, so the oxide film can be formed in a uniform thickness on the surface on the wafer 29. Both or either of the oxide reaction or the thermal CVD reaction are assumed to contribute to forming this oxide film. More specifically, the oxide reaction is assumed to be the main contributor in the first few minutes, and the CVD (deposit) is thought to be main contributor in the remaining time.

The oxide film can be formed on the wafer 29 at a high oxide film forming speed even when the processing temperature in the oxide film forming method is a comparatively low temperature below 500° C., because the oxidizer 37 supplied by the oxidizer supply device 30 contains OH* possessing a powerful oxidizing effect as previously described and so the oxide film can be formed in a short time. A processing temperature higher than 500° C. is not desirable since it exerts adverse effects on the previously formed semiconductor devices and circuit patterns on the wafer 29. Moreover a processing temperature lower than 100° C. is not desirable since it becomes more difficult to cause the oxide reaction and CVD reaction. The processing temperature should therefore preferably be set at 100° C. or more and 500° C. or less.

When the preset processing time has elapsed, the boat 27 is lowered by the boat elevator 28 so that the boat 27 holding the processed wafers 29 is unloaded (boat unloading) from the processing chamber 14 to the original standby position.

The oxide film forming device 10 then repeats the above described processing of the wafers 29 as batch processing. The embodiment therefore yields the following effects.

1. An oxide film can be formed on the wafer at a high oxide film forming speed even when the processing temperature in the oxide film forming method is a comparatively low temperature below 500° C. by bubbling ozone in the water to generate an oxidizer containing OH* and supplying it to the processing chamber so that the oxide film can be formed on the wafer at relatively low temperatures in a short time.

2. An oxide film forming method utilizing OH* is achieved by bubbling ozone in water to generate an oxidizer containing OH* so that OH* is efficiently generated compared to the method that generates OH* by mixing ozone and steam.

3. An oxide film can be formed on a wafer in a short time at maximum temperatures (for example 500° C.) without exerting harmful effects on semiconductor devices and circuit patterns previously formed on the wafer. These advantages are obtained because the oxidizer containing OH* exhibits a powerful oxidizing effect even at temperatures of 400° C. or more being capable of attaining satisfactory oxide film forming speed, because unlike ozone, the OH* does not decompose at high temperatures of 400° C. or more. The temperature during processing is preferably not set below 100° C. since it is difficult to cause an oxidizing reaction and CVD reaction.

4. Unforeseen plasma damage such as to the semiconductor devices and circuit patterns previously formed on the wafer are prevented since plasma is not used by bubbling ozone in water to generate an ozonizer containing OH* and supplying the oxidizer to the processing chamber to form the oxide film. The film is therefore formed without having to use plasma.

5. The throughput, performance and reliability of the oxide film forming device is improved by the above items 1 through 4.

6. The invention can efficiently generate OH* since the consumption of the ozone by impurities in water during bubbling is inhibited by bubbling ozone in deionized water that contains almost no impurities. A fine quality film can be formed since there are few impurities.

The IC manufacturing method of the second embodiment of the present invention is described next.

When the minimum IC processing dimensions shrink to 0.1 μm or less, the gate process and contact forming processes require that a substrate surface cleaning process (step) be continuously implemented as a preprocessing step in order to remove natural oxide film and organic contamination and metal contamination substances on the surface of the substrate (wafer) as the object to be processed prior to the film forming process (step). The IC manufacturing method of the present embodiment is characterized by this preprocessing step. In other words, in this method, after the wafers are conveyed from the load-lock chamber to the cleaning unit for the pre-cleaning process, the wafers are then continuously conveyed to the CVD unit without being exposed in the air and the film forming process is performed.

The cleaning devices of the prior art for pre-cleaning in the contact forming process, include feeding an etching gas excited by plasma, and exciting the etching gas with ultra-violet rays. However, when the aspect ratio of the contact pattern becomes large or the shape becomes complicated, then the etching gases in conventional cleaning devices of this type are consumed in the upper section of the hole and the gas sometimes does not reach the bottom of the hole, or the ultraviolet rays sometimes do not reach to the bottom of the hole. Methods have been attempted to set a lower pressure to extend the mean free path for the activated substance to allow reaching the bottom of the hole of a contact pattern with a high aspect ratio. However, this method cannot be employed because the plasma cannot be excited unless the pressure is in a comparatively high region. In the present invention however, the gas contains OH* generated by bubbling ozone in water so that setting a lower pressure extends the mean free path or using at a higher partial pressure allows reaching the bottom even on contact patterns with large aspect ratios and complicated patterns.

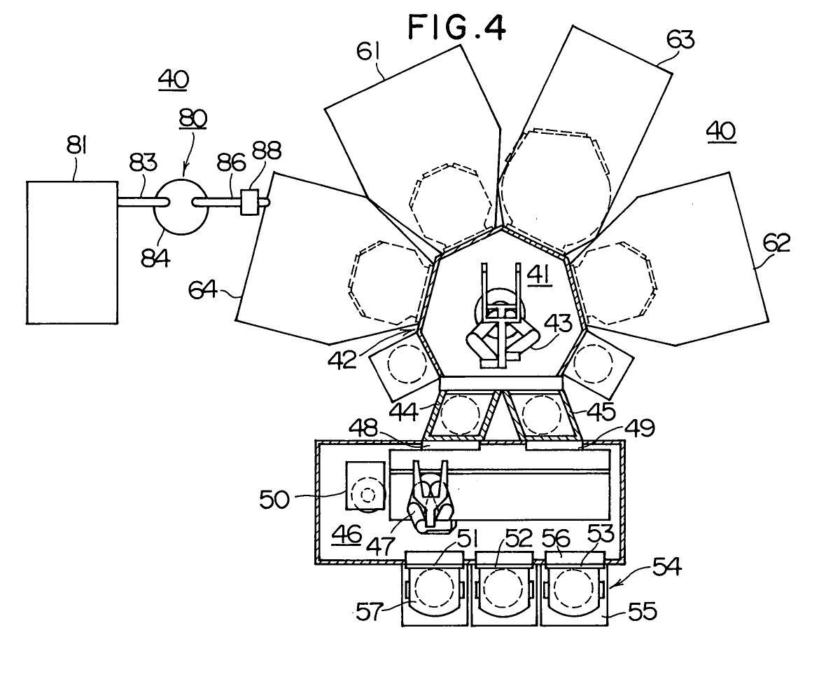

The IC manufacturing method of the present embodiment includes a contact forming process implemented in the multichamber device shown in FIG. 4. This method includes a pre-cleaning step (cleaning process) that removes natural oxide film and organic contamination and metal contamination substances on the surface of the substrate by making use of the etching properties of the gas containing OH* generated by bubbling ozone in water.

A multichamber device 40 shown in FIG. 4 contains a first wafer transfer chamber (hereafter called negative pressure transfer chamber) 41 comprised of a load-lock chamber structure to withstand pressure below atmospheric pressure (hereafter called negative pressure). A case 42 of the negative pressure transfer chamber 41 as seen from a plan view has a heptagon form and is formed in box shape sealed at top and bottom. A wafer transfer device (hereafter called negative pressure transfer device) 43 for loading the wafers 29 under a negative pressure is installed in the center of the negative pressure transfer chamber 41. The negative pressure transfer device 43 is comprised of a SCARA (selective compliance assembly robot arm) robot.

The side walls positioned on the front side among the seven side walls in the negative pressure transfer chamber case 42 are connected adjacent to a loading prechamber (hereafter called unloading chamber) 44 and an unloading pre chamber (hereafter called unloading chamber) 45. The case of the loading chamber 44 and the case of the unloading chamber 45 respectively have diamond shapes as seen from a plan view and are formed in a box shape sealed at both the top and bottom ends and are comprised of a load-lock chamber structure to withstand negative pressure. A second wafer transfer chamber (hereafter called positive pressure transfer chamber) 46 with a structure capable of maintaining a pressure higher than atmospheric pressure (hereafter called positive pressure) is connected adjacent to the front sides of the loading chamber 44 and unloading chamber 45. The case of the positive pressure transfer chamber 46 is formed in a box shape having a laterally long rectangle as seen from a plan view and sealed at the top and bottom ends. A wafer transfer device (hereafter called positive pressure transfer device) 47 for setting the wafers 29 under a positive pressure is installed in the positive pressure transfer chamber 46. The positive pressure transfer device 47 is comprised of a SCARA robot. The positive pressure transfer device 47 is structured to move up and down by an elevator installed in the positive pressure transfer chamber 46. The positive pressure transfer device 47 is also structured to move to the left and right by means of a linear actuator.

A gate valve 48 is installed on the boundary of the loading chamber 44 and the positive pressure transfer chamber 46. A gate valve 49 is installed on the boundary of the unloading chamber 45 and the positive pressure transfer chamber 46. A notch aligning device 50 is installed on the left side portion of the positive pressure transfer chamber 46. Three wafer load/unload openings 51, 52, 53 are formed arrayed from left to right on the front wall of the positive pressure transfer chamber 46. The three wafer load/unload openings 51, 52, 53 are structured to load and unload the wafers 29 to and from the positive pressure transfer chamber 46. Pod openers 54 are respectively installed in these wafer load/unload openings 51, 52, 53. The pod openers 54 include a mount stand 55 for mounting pods 57, and a cap fitter/remover 56 for fitting or removing the cap of the pod 57 mounted on the mount stand 57. The wafer load/unload opening of the pod 57 is opened and closed by the cap fitter/remover 56 fitting on or removing the cap of the pod 57 placed on the mount stand 57. The pod 57 for the mount stand 55 of the pod opener 54 is supplied or ejected by means of an in-process conveyor device (RGV) not shown in the drawing.

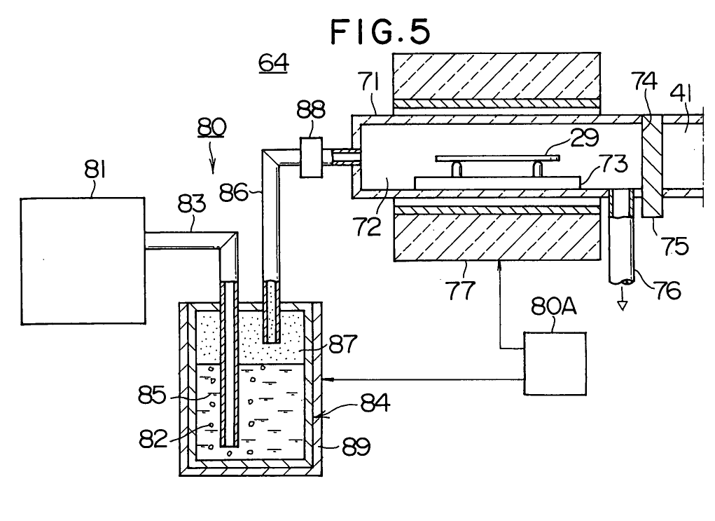

A first CVD unit 61, a second CVD unit 62, an annealing unit 63 and a cleaning unit 64 are respectively connected to four side walls positioned on the rear side of the negative pressure transfer chamber 42. The first CVD unit 61 and the second CVD unit 62 are comprised of single wafer CVD processing devices. The annealing unit 63 is comprised of a single wafer heat processing device. The cleaning unit 64 structured as shown in FIG. 5, utilizes the etching properties of gas containing OH* generated by bubbling ozone in water to perform a pre-cleaning step (cleaning process) for removing the natural oxide film and organic contamination and metal contamination substances.

As shown in FIG. 5, the cleaning unit 64 contains a process tube 71 formed using heat-resistant and anti-corrosion material such as quartz. A processing chamber 72 for performing the cleaning process on the wafers 29 is formed inside the process tube 71. A support stand 73 for supporting the wafers 29 in a horizontal position is installed inside the processing chamber 72. A wafer load/unload opening 74 is formed at the boundary with the negative pressure transfer chamber 41 of the process tube 71. A gate valve 75 is structured to open and close the wafer load/unload opening 74. One end of an exhaust pipe 76 is connected to the process tube 71 to communicate with the processing chamber 72. The other end of the exhaust pipe 76 is connected to the exhaust device (not shown in drawing) made up of a vacuum pump, etc. A heater unit 77 for heating the processing chamber 72 is installed on the outside of the process tube 71. An etching gas supply device 80 for supplying gas (hereafter called etching gas) generated by bubbling ozone in deionized water to the processing chamber 72 is connected to the process tube 71. The etching gas supply device 80 is comprised of a ozonizer 81 for generating ozone 82, a bubbler 84 wherein deionized water 85 is kept and the blow vent of an ozone supply pipe 83 for supply the ozone 82 generated by the ozonizer 81 is immersed in the deionized water 85 as to form ozone bubbles, and a supply pipe 86 for supplying etching gas 87 containing OH* generated by bubbling ozone 82 in the deionized water 85 to the processing chamber 72. A mass flow controller (MFC) 88 is installed as a flow rate control means to control the flow rate of the etching gas between the etching gas supply device 80 and the processing chamber 72. A heater 89 for heating the deionized water 85 in the bubbler 84 is installed in the bubbler 84 and is also structured to maintain the deionized water 85 in a heated state during bubbling. The temperature of the deionized water 85 during bubbling is preferably at room temperature but may also be a temperature higher than room temperature. For example a temperature that boils the water may be used.

The cleaning unit 64 contains a temperature controller 80A. The heater unit 77 and the heater 89 are connected to the temperature controller 80A. The temperature controller 80A controls the heater unit 77 and the heater 89 so as to maintain the processing temperature during cleaning of the wafer at a higher temperature than the temperature of the deionized water 85 in the bubbler 84 or at a temperature between 50° C. to 400° C.

The contact forming process in the IC manufacturing method using the above multichamber device is described next centering mainly cleaning step.

The pod 57 is placed on the mount stand 55 of the pod opener 54 from the in-process conveyor device. The cap of the pod 57 is removed by the cap fitter/remover 56 and the wafer load/unload opening of the pod 57 is opened. When the pod opener 54 opens the pod 57, the positive pressure transfer device 47 installed in the positive pressure transfer chamber 46 picks up the wafers 29 one at a time in sequence from the pod 57, loads them into the loading chamber 44 (wafer loading), and sets the twenty-five wafers 29 stored in one pod 57, onto the temporary stand for the loading chamber. When loading the wafers 29 into the loading chamber 44 is complete, the gate valve 48 closes the loading chamber 44, and the loading chamber 44 is exhausted to the negative pressure by the exhaust device (not shown in drawing).

When the loading chamber 44 decompresses to a preset pressure value, the load opening on the negative pressure transfer chamber 41 side is opened by the gate valve, and the wafer load/unload opening 74 of the cleaning unit 64 is opened by the gate valve 75. The negative pressure transfer device 43 of the negative pressure transfer chamber 41 next picks up the wafers 29 one at a time from the loading chamber 44, loads them to the negative pressure transfer chamber 41, and along with loading them via the wafer load/unload opening 74 into the processing chamber 72 of the cleaning unit 64 (wafer loading), sets the wafers 29 on the support stand 73 of processing chamber 72. When setting the wafers 29 onto the support stand 73 is complete, the gate valve 75 closes the wafer load/unload opening 74 of the cleaning unit 64.

The exhaust pipe 76 next exhausts the processing chamber 72 to the specified pressure when the processing chamber 72 is closed, and the heater unit 77 heats the chamber to a specified processing temperature between 50° C. and 500° C. or preferably between 50° C. and 400° C. under the control of the temperature controller 80A. Next, the etching gas supply device 80 supplies the etching gas 87 containing OH* generated by bubbling ozone in the deionized water 85, by way of the mass flow controller 88 to the processing chamber 72. In other words, the ozonizer 81 blows ozone 82 from the ozone supply pipe 83 into the deionized water 85 for bubbling. The temperature controller 80A in this case controls the heater unit 77 and the heater 89 so that the processing temperature is higher than the bubbling deionized water 85. The etching gas 87 containing OH* is generated by bubbling the ozone 82 in the deionized water, and the etching gas 87 is discharged into the space above the deionized water 85 in the bubbler 84. The etching gas 87 discharged into the space above the deionized water 85 in the bubbler 84, is extracted from the bubbler 84 by the supply pipe 86, the flow is regulated to a specified flow rate by the mass flow controller 88, and the etching gas 87 is supplied to the processing chamber 72. The etching gas 87 supplied to the processing chamber 72 contacts the surface of the wafer 29 and removes the natural oxide film, organic contamination and metal contamination substances formed on the surface of the wafer 29. The etching gas 87 supplied by the etching gas supply device 80 here has a powerful oxidizing effect since it contains OH* as described above and is therefore capable of removing the natural oxide film, organic contamination and metal contamination substances.

A processing temperature lower than 50° C. or higher than 400° C. is not preferable since it is difficult for the etching reaction to occur. Therefore the processing temperature is preferably set to a temperature of 50° C. or more and 400° C. or less during etching.

When the cleaning process time that was preset on the cleaning unit 64 has elapsed and the cleaning is complete, the cleaned wafers 29 are unloaded (wafer unloading) by the negative pressure transfer device 43 from the cleaning unit 64 into the negative pressure transfer chamber 41 maintained at a negative pressure. When the now cleaned wafers 29 are unloaded into the negative pressure transfer chamber 41 from the cleaning unit 64, the gate valve opens the wafer load/unload opening of the first CVD unit 61. Next, the negative pressure transfer device 43 loads the wafers 29 unloaded from the cleaning unit 64, into the first CVD unit 61. When the wafers 29 have been shifted from the cleaning unit 64 to the first CVD unit 61, the gate valve closes the first CVD unit 61.

In the first CVD unit 61, the processing chamber is next exhausted to a specified pressure by the exhaust pipe, and heated by the heater unit to a specified temperature. A desired first film matching the desired preset conditions is then formed on the wafer 29 by supplying the specified material gas at just the specified flow rate through the gas feed pipe. When the preset film forming time has elapsed in the first CVD unit 61, the negative pressure transfer device 43 picks up the wafers 29 formed with their first film from the first CVD unit 61, and unload them into the negative pressure transfer chamber 41 maintained at a negative pressure (wafer unloading). When the now processed wafers 29 are unloaded from the first CVD unit 61 into the negative pressure transfer chamber 41, the gate valve opens the wafer load/unload opening of the second CVD unit 62. Next, the negative pressure transfer device 43 loads the wafers 29 that were unloaded from the first CVD unit 61, into the second CVD unit 62.

A second film is formed in the second CVD unit 62 by performing the same processing as in the first CVD unit 61. Afterwards, the wafers 29 formed with a second film, are conveyed by the negative pressure transfer device 43 from the second CVD unit 62 to the annealing unit 63 by way of the negative pressure transfer chamber 41. Annealing is performed in the annealing unit at a specified atmosphere and a specified temperature.

The substrate surface cleaning process by the cleaning unit 64, the first film forming process by the first CVD unit 61, the second film forming process by the second CVD unit 62, and the thermal treatment process by the annealing unit 63 are performed in sequence by repeating the above described processing on the twenty-five wafers 29 loaded into the loading chamber 44. When the specified series of processes have been performed on the twenty-five wafers 29, the now processed wafers 29 are returned to the empty pod 57.

The embodiment yields the following effects.

1. Etching gas containing OH* generated by bubbling ozone in water can reach even the bottom of contact patterns with complex shapes and contact patterns with large aspect ratios and so is capable of removing the natural oxide film, organic contamination and metal contamination substances formed on the bottom surface of contact patterns with large aspect ratios and complex contact patterns.

2. By generating etching gas containing OH* generated by bubbling ozone in water and supplying this etching gas to the processing chamber, damage by plasma to semiconductor devices and circuit patterns previously formed on the wafer can be prevented since no plasma is used.

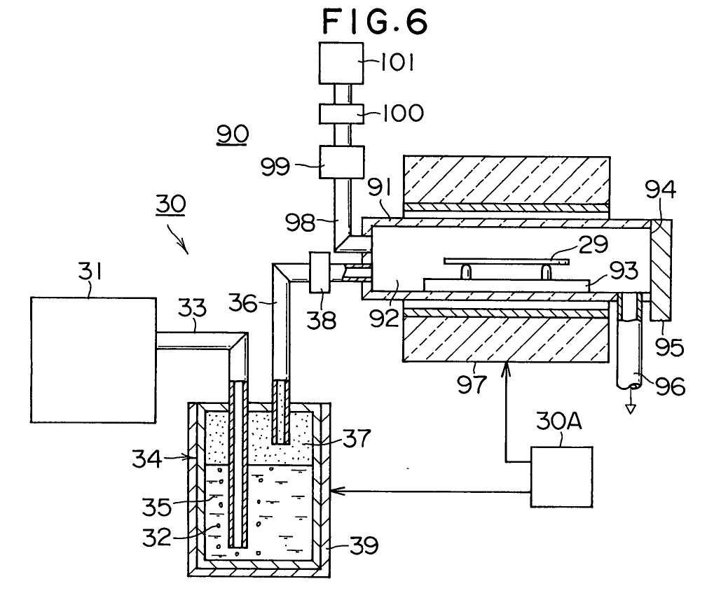

The third embodiment of the present invention is an IC manufacturing method comprising a process for forming thin films such as semiconductor oxide films (for example, SiO₂) or metallic oxide films (for example, ZrO₂, HfO₂, Ta₂O₅ etc.) by thermal CVD reaction. A MOCVD (Metal Organic Chemical Vapor Deposition) device 90 as shown in FIG. 6 is used to implement the thin film forming method of the present embodiment. The MOCVD device 90 as shown in FIG. 6 is provided with a process tube 91 that forms a processing chamber 92. A support stand 93 for holding the wafer 29 horizontally is installed in the processing chamber 92. A gate valve 95 opens and closes a wafer load/unload opening 94 formed on the sidewall of the process tube 91. An exhaust pipe 96 for exhausting the processing chamber 92 connects to another position on the process tube 91. A heater unit 97 for heating the processing chamber 92 is installed outside the process tube 91. A material gas supply pipe 98 for supplying material gas to the processing chamber 92 is connected to the process tube 91. A vaporizer 99, a fluid flow rate controller 100, a liquid material container 101 are connected in sequence to the material gas supply pipe 98 from the processing chamber 92 side. An oxidizer supply device is connected to another position on the process tube 91. The structure of this oxidizer supply device is identical to the oxidizer supply device 30 of the first embodiment so the same reference numerals are assigned and a description is omitted.

In the present embodiment, the material gas from the material gas supply pipe 98 (for example, gas containing semiconductor elements, or gas from gasification liquid materials containing semiconductor elements or metallic elements), and the gas (oxidizer) from the oxidizer supply device 30 containing OH* generated by bubbling ozone in water, are supplied to the processing chamber 92 holding the wafers 29, and then subjected to CVD reaction by maintaining a specified pressure and a specified temperature between 100 and 500° C. The temperature controller 30A in this case controls the heater unit 97 and the heater 39 to set the processing temperature to a specified temperature higher than the temperature of the deionized water 35 for bubbling. The CVD reaction with this material gas and the gas forms the semiconductor oxide film or metallic oxide film on the wafer 29.

Silane based gases such as SiH₄, Si₂H₆, SiH₂Cl₂, SiCl₆ are examples of material gases containing semiconductor elements used when forming semiconductor oxide film such as SiO₂, etc.

Examples of liquid materials containing metallic elements, and liquid materials containing semiconductor elements used when forming semiconductor oxide films such as SiO₂, or forming metallic oxide films such as ZrO₂, HfO₂, Ta₂O₅ are:

TEOS (tetraethoxysilane (Si(OC₂H₅)₄)),

BTBAS (bistertiarybutylaminosilane (SiH₂(NH(C₄H₉))₂)),

Si-(MMP) 4 (tetrakis(1-methoxy-2-methyl-2-propoxy)silicon (Si[OC(CH₃)₂CH₂OCH₃]₄))

Zr-(MMP) 4 (tetrakis(1-methoxy-2-methyl-2-propoxy) zirconium (Zr[OC(CH₃)₂CH₂OCH₃]₄))

Hf-(MMP) 4 (tetrakis(1-methoxy-2-methyl-2-propoxy)hafnium (Hf[OC(CH₃)₂CH₂OCH₃]₄))

PET (pentaethoxytantalum) (Ta(OC₂H₅)₅),

Tetrakisdiethylamidehafnium (Hf[N(C₂H₅)₂]₄),

Tetrakisdimethylamidehafnium (Hf[N(CH₃)₂]₄),

Tetrakismethyethylamidehafnium (Hf[N(CH₃)(C₂H₅)]4),

Tetrakisdiethylamidesilicon (Si[N(C₂H₅)₂]₄),

Tetrakisdimethylamidesilicon (Si[N(CH₃)₂]₄),

Tetrakismethylethylamidesilicon (Si[N(CH₃)(C₂H₅)]₄),

Trisdiethylamidesilicon (H—Si[N(C₂H₅)₂]₃),

Trisdiethylamidesilicon (H—Si[N(CH₃)₂]₃),

Trismethylethylamidesilicon (H—SiN(CH₃)(C₂H₅)]₃).

A method such as the ALD (Atomic Layer Deposition) method may also be used to form the film. In this method when processing the wafer, the temperature is lowered even further than the processing temperature used for bringing about the CVD reaction, and the material gas and the oxidizer (gas generated by bubbling O₃ in water) are alternately each supplied to the wafer to form the film. In that case, the following reaction occurs on the wafer. Namely, the material gas attaches to the wafer surface without any reaction taking place, by supplying the material gas to the wafer at a temperature where the material will not decompose. By afterwards supplying an oxidizer (gas generated by bubbling O₃ in water) to the wafer on which the material is adhering, a reaction occurs between the oxidizer and the material adhering to the wafer surface, and a film automatically is formed on the wafer surface. A film can be formed in one atom layer at a time on the wafer by repeating this process. A gas replacement process is preferably provided at this time for raising a vacuum or purging for example with inert gas (N₂), in the period between the material gas supply process and the oxidizer supply process. In other words, defining the material gas supply process→gas replacement process→oxidizer supply process→gas replacement process as one cycle, the processing is preferably performed by repeating this cycle multiple times.

The fourth embodiment of the present invention is an IC manufacturing method including a process for etching silicon oxide. The structure of the etching device of the present embodiment is identical to the cleaning unit 64 of the second embodiment. In the present embodiment, SiO₂ etching is performed by supplying a gas (etching gas) containing OH* generated by bubbling ozone in water, to a reaction chamber (etching chamber), and maintaining a specified temperature of 50° C. to 400° C. and a specified pressure for a specified time. The etching gas containing OH* generated by bubbling ozone in water possesses etching properties for silicon oxide as previously described so there is a large degree of selectability when etching silicon oxide. The present embodiment is also applicable to etching of semiconductor film (such as, silicon nitriding film) or metallic film (such as aluminum).

In the second embodiment and the fourth embodiment, the reaction of the gas (etching gas) generated by bubbling ozone (O₃) in water does not occur immediately even if the etching gas is supplied to a heated reaction chamber. The reaction instead tends to occur within a latent period where an excitation state has occurred. In other words, in a period after the gas (etching gas) generated by bubbling ozone (O₃) in water was supplied to the reaction chamber, an oxygen reaction occurs without an etching reaction occurring on the substrate (wafer), then after a certain period of time elapses, the etching reaction is thought to occur when an excitation state has been reached.

During the oxidation process and during the etching process, there is a range (100° C. to 400° C.) where process temperatures overlap. The process to be performed in this temperature range may be selected by controlling the process time.

In the above embodiments, the case was described where ozone was bubbled in deionized water to generate an activated gas. However, the liquid for bubbling may be a liquid capable of generating substance containing hydroxyl or in other words, OH radicals by bubbling ozone and may at least be a liquid containing hydrogen (H) atoms. Moreover, the liquid may be a liquid containing oxygen (O) atoms, namely, at least hydrogen (H) atoms and oxygen (O) atoms. Also, the liquid may be a liquid containing at least hydroxyl. For example, the liquid may simply be water (H₂O) not pure water. Besides H₂O, hydrogen peroxide water solution (H₂O₂), or hydrogen chloride (HCl) solution etc. may be utilized.

The present invention is not limited by the above described embodiments and needless to say, and may include adaptations and variations not departing from the spirit and scope of the invention.

For example, the gas generated by bubbling ozone in water may be applied to the cleaning of organic matter or the sterilizing of germs, etc. Besides a method for manufacturing ICs, the invention may apply to general oxidizing and cleaning processes in the foodstuff manufacture and the medical treatment fields, etc.

1. A manufacturing method for semiconductor devices comprising the steps of: loading an object to be processed into a processing chamber, generating an activated gas by bubbling ozone in fluid containing at least hydrogen atoms, supplying the generated gas into the processing chamber and processing the object to be processed, and unloading the object to be processed from the processing chamber after processing, wherein the processing temperature in the step for processing the object to be processed is greater than the temperature of the fluid containing hydrogen atoms.

2. A manufacturing method for semiconductor devices comprising the steps of: loading an object to be processed into a processing chamber, generating an activated gas by bubbling ozone in fluid containing at least hydrogen atoms, supplying the generated gas into the processing chamber and processing the object to be processed, and unloading the object to be processed from the processing chamber after processing, wherein the processing temperature in the step for processing the object to be processed is 100 to 500° C.

3. A manufacturing method for semiconductor devices comprising the steps of: loading an object to be processed into a processing chamber, generating an activated gas by bubbling ozone in fluid containing at least hydrogen atoms, supplying the generated gas into the processing chamber and forming an oxide film on the object to be processed, and unloading the object to be processed from the processing chamber after processing.

4. A manufacturing method for semiconductor devices comprising the steps of: loading an object to be processed into a processing chamber, generating an activated gas by bubbling ozone in fluid containing at least hydrogen atoms, supplying the generated gas into the processing chamber and etching an oxide film formed on the object to be processed, and unloading the object to be processed from the processing chamber after processing.

5. A manufacturing method for semiconductor devices comprising the steps of: loading an object to be processed into a processing chamber, generating an activated gas by bubbling ozone in fluid containing at least hydrogen atoms, supplying the generated gas and material gas into the processing chamber and forming a film on the object to be processed by thermal CVD method, and unloading the object to be processed from the processing chamber after processing.

6. A manufacturing method for semiconductor devices comprising the steps of: loading an object to be processed into a processing chamber, processing the object to be processed in the processing chamber, unloading the object to be processed from the processing chamber after processing, generating an activated gas by bubbling ozone in fluid containing at least hydrogen atoms, supplying the generated gas into the processing chamber with the object to be processed unloaded to remove contamination substance in the processing chamber.

7. A manufacturing method for semiconductor devices according to claim 1, wherein in the step for processing the object to be processed, an oxide film is formed on the object to be processed or a film is formed on the object to be processed by thermal CVD method in an atmosphere containing the generated gas and material gas.

8. A manufacturing method for semiconductor devices according to claim 1, wherein in the step for processing the object to be processed, an oxide film formed on the surface of the object to be processed is etched, or a semiconductor or a metal as the object to be processed is etched, or a natural oxide film or organic contamination substance or metal contamination substance formed on the surface of the object to be processed is removed.

9. A manufacturing method for semiconductor devices according to claim 7, wherein the processing temperature in the step for processing the object to be processed is 100 to 500° C.

10. A manufacturing method for semiconductor devices according to claim 8, wherein the processing temperature in the step for processing the object to be processed is 50 to 400° C.

11. A manufacturing method for semiconductor devices according to claim 2, wherein in the step for processing the object to be processed, an oxide film is formed on the object to be processed, or a film is formed on the object to be processed by thermal CVD method in an atmosphere containing the generated gas and material gas.

12. A manufacturing method for semiconductor devices according to claim 1, wherein hydroxyl (OH) radicals are generated in the step for generating the activated gas.

13. A manufacturing method for semiconductor devices according to claim 1, wherein the activated gas is a gas containing a hydroxyl.

14. A manufacturing method for semiconductor devices according to claim 1, wherein the fluid for bubbling the ozone is a fluid containing at least hydrogen (H) atoms and oxygen (O) atoms.

15. A manufacturing method for semiconductor devices according to claim 1, wherein the fluid for bubbling the ozone is water (H₂O).

16. A manufacturing method for semiconductor devices according to claim 1 wherein the fluid for bubbling the ozone is deionized water (pure water).

17. A manufacturing method for semiconductor devices according to claim 1, wherein the fluid for bubbling the ozone is hydrogen peroxide water solution (H₂O₂).

18. A manufacturing method for semiconductor devices according to claim 1, wherein the fluid for bubbling the ozone contains hydrogen chloride (HCl).

19. A manufacturing method for semiconductor devices according to claim 1, wherein the fluid for bubbling the ozone is a fluid containing at least a hydroxyl.

20. A substrate processing apparatus comprising: a processing chamber for processing an object to be processed, a heater for heating the object to be processed in the processing chamber, an ozonizer for generating ozone, a bubbler for generating activated gas by bubbling ozone generated by the ozonizer in fluid containing at least hydrogen atoms, a supply pipe for supplying the activated gas generated by the bubbler into the processing chamber, and a control means for regulating the processing temperature during processing of the object to be processed so that the processing temperature is higher than the temperature of the fluid containing hydrogen atoms.
